(19) United States
(12) Patent Application Publication
(10) Pub. No.: US 2003/0119233 A1
(43) Pub. Date: Jun. 26, 2003

(54) Method of fabricating semiconductor device with T-type gate electrode

(75) Inventor: Hirosada Koganei, Kawasaki-shi (JP)

Correspondence Address: Norman P. Soloway, HAYES SOLOWAY PC, 130 W. Cushing Street, Tucson, AZ, 85701, US

(73) Assignee: NEC Compound Semiconductor Devices, Ltd.

(21) Appl. No.: 10/321,944

(22) Filed: Dec. 17, 2002

(30) Foreign Application Priority Data
Dec. 20, 2001 (JP) 2001-387764

(51) Int. Cl. H01L 21/338

(52) U.S. Cl. 438/182

(57) ABSTRACT

A method of fabricating a semiconductor device is provided, which eliminates the possibility that the surface of a recess is contaminated before and after the process of forming a gate electrode, and which achieves sufficient controllability of the shape of a gate electrode. First and second dielectric layers, which have been formed successively to cover the recess of a semiconductor base material, are selectively removed by dry etching at approximately equal etch rates, thereby forming a gate opening that penetrates the second and first dielectric layers to reach the surface of the base material in the recess. A gate electrode with an approximately T-shaped cross section is formed to contact the surface of the base material in the recess by way of the gate opening. The second dielectric layer is selectively removed by wet etching at an etch rate sufficiently greater than an etch rate of the first dielectric layer, exposing the first dielectric layer.

### BACKGROUND OF B THE INVENTION

1. Field of the Invention

The present invention relates generally to a method of fabricating a semiconductor device. More particularly, the invention relates to a method of fabricating a semiconductor device having a semiconductor base material with a recess formed on its surface, and a T-type gate electrode an end of which is contacted with the surface of the base material in the recess, where the gate electrode has an approximately T-shaped cross section. The invention is preferably applicable to fabrication of semiconductor devices having excellent high-frequency performance, such as Schottky-gate Field-Effect Transistors (FETs) using compound semiconductor.

2. Description of the Related Art

FETs having a T-shaped or T-type gate electrode, which have ever been extensively used for mobile communication and satellite communication, are typically made of, for example, a III-V compound semiconductor (e.g., GaAs) or semiconductors. The T-shaped gate electrode of the FETs of this type is employed to suppress the gate resistance increase. Specifically, if the gate length is reduced to correspond to the tendency of raising the signal frequency used, the cross section along the signal propagation direction of the gate electrode (i.e., the gate cross-sectional area) is reduced, resulting in the resistance increase in the same direction (i.e., the gate resistance increase). Thus, the gate cross-sectional area is increased by making the gate cross-section approximately T-shaped at an opposite end of the gate electrode to the semiconductor substrate while keeping the gate length as short as possible. As a result, the gate resistance increase induced by the gate length decrease is suppressed by the use of the T-shaped gate electrode.

Moreover, with the FETs of this type, the gate electrode is formed on the surface of a crystalline semiconductor base material. It is known that the depletion layer, which is formed in the surface region of the base material directly below the gate electrode on operation, applies a bad effect to the operation of the FET. To suppress the bad effect in question, it is typical that a “recess” is formed at an area of the surface of the base material right below the gate electrode. Usually, the said “recess” occupies only the area right below the gate electrode, or the area right below the gate electrode and its neighboring area. The source electrode and the drain electrode are arranged on the surface of the base material on opposite sides to each other with respect to the recess (i.e., the gate electrode).

Next, a prior-art method of fabricating a FET of this type having the T-type gate electrode and the recess is explained below with reference to FIGS. 1A to 1D which show the partial, schematic cross-sectional views of the FET, respectively.

First, an active layer 102, which is typically made of GaAs, is formed on the surface of a single-crystal semiconductor (e.g., GaAs) substrate 101 by an epitaxial growth method. Then, the single-crystal active layer 102 thus formed is selectively etched to form a recess 104 with a specific depth, as shown in FIG. 1A. The recess 104 is located at a position in which a gate electrode 107 will be formed later. The recess 104 is formed to cover approximately the whole width of a gate electrode to be formed thereon. Here, the combination of the single-crystal substrate 101 and the single-crystal active layer 102 constitutes a single-crystal “semiconductor base material”.

Subsequently, a SiO₂ (silicon dioxide) layer 103 with a specific thickness is formed on the active layer 102 in such a way as to cover the recess 104. A photoresist film 105 with a specific pattern is then formed on the SiO₂ layer 103 thus formed. Using the photoresist film 105 as a mask, the SiO₂ layer 103 is selectively removed by a dry etching method, forming an opening 106 for a gate electrode. As a result, the surface of the active layer 102 in the recess 104 (i.e., the surface of the recess 104) is partially exposed from the layer 103. The state at this stage is shown in FIG. 1A.

Next, the photoresist film 105 is removed and thereafter, a T-shaped gate electrode 107 is formed by a known method, as shown in FIG. 1B. At this time, the whole width of the gate electrode 107, which is measured perpendicular to the straight line connecting the source and drain electrodes 109 and 110 to each other, is set in such a way as to approximately in accordance with the whole width of the recess 104. As seen from FIG. 1B, the whole length of the gate electrode 107, which is measured along the straight line connecting the source and drain electrodes 109 and 110 to each other, is shorter than the length of the recess 104. Since the recess 104 is not exposed in the state of FIG. 1B, there is no possibility that the exposed surface of the recess 104 is contaminated. However, the thick SiO₂ layer 103 exists just below the two overhanging parts of the gate electrode 107 (i.e., the two laterally protruding parts of the electrode 107 located at its top) and therefore, the gate parasitic capacitance is large. As a result, the characteristics of the FET will degrade.

To avoid this disadvantage, the SiO₂ layer 103 is entirely removed by a wet etching method using hydrofluoric (HF) acid. The state at this stage is shown in FIG. 1C, where the surface of the active layer 102 is exposed approximately entirely except for the portion where the gate electrode 107 contacts. Therefore, there is high possibility that the exposed surface of the recess 104 is contaminated in the state of FIG. 1C.

Following this process step, a protection layer 108 is formed to cover the whole exposed surface of the gate electrode 107 and the whole exposed surface of the active layer 102. As the protection layer 108, for example, a silicon nitride (Si₃N₄) layer is used.

An opening for a source electrode and an opening for a drain electrode are formed at their corresponding positions of the protection layer 108 by an etching method, thereby exposing the underlying active layer 102 from the layer 108 by way of these openings. Then, a source electrode 109 and a drain electrode 110 are formed in such a way that the bottoms of the electrodes 109 and 110 contact the surface of the active layer 102 by way of their respective openings of the layer 108. The state at this time is shown in FIG. 1D.

Finally, a necessary dielectric layer and a wiring conductive layer (both not shown) are formed on the protection layer 108 by a known method to cover the gate electrode 107, the source electrode 109, and the drain electrode 110. Thus, the FET with the recess 104 and the T-shaped gate electrode 107 thereon is completed.

As seen from the above-described explanation, with the prior-art method shown in FIGS. 1A to 1D, almost all the surface of the active layer 102 including the recess 104 is temporarily exposed in the state of FIG. 1C. Thus, there is a disadvantage that the surface of the recess 104 is liable to be contaminated before the surface of the layer 102 is covered with the protection layer 108 in the later step. This means that malfunction of the FET is likely to occur and that the fabrication yield tends to degrade.

Next, another prior-art method of fabricating the FET of the same type as above is explained below with reference to FIGS. 2A to 2E.

In this method, first, an active layer 202, which is typically made of GaAs, is formed on the surface of a single-crystal semiconductor (e.g., GaAs) substrate 201 by an epitaxial growth method. Then, the single-crystal active layer 202 thus formed is selectively etched to form a recess 205 with a specific depth, as shown in FIG. 2A. The recess 205 is located at a position in which a gate electrode will be formed later. The recess 205 is formed to cover approximately the whole width of a gate electrode. Here, the combination of the single-crystal substrate 201 and the single-crystal active layer 202 constitutes a single-crystal “semiconductor base material”.

Subsequently, a Si₃N₄ layer 203 with a specific thickness and a SiO₂ layer 204 with a specific thickness are successively formed on the active layer 202 in such a way as to cover the recess 205. The state at this stage is shown in FIG. 2A.

Thereafter, a photoresist film 206 with a specific pattern is formed on the SiO₂ layer 204. Using the photoresist film 206 as a mask, the SiO₂ layer 204 and the Si₃N₄ layer 203 are selectively removed by a dry etching method, forming an opening 207 for a gate electrode. The opening 207 penetrates vertically both the layers 204 and 203 to reach the surface of the recess 205.

The dry etching process for patterning the layers 204 and 203 is carried out by a Reactive Ion Etching (RIE) method using the mixture of CF₄ and H₂ as an etching gas. By the use of a RIE method under this condition, the resultant cross-sectional shape of the opening 207 is not uniform or straight due to the etch rate difference between the SiO₂ layer 204 and the Si₃N₄ layer 203 but is stepped, as shown in FIG. 2B. Specifically, the Si₃N₄ layer 203 in the lower level is side-etched (i.e., etched laterally) greater than the SiO₂ layer 204 in the upper level and therefore, the opening 207 at the part corresponding to the Si₃N₄ layer 203 is laterally wider than that at the part corresponding to the SiO₂ layer 204. The surface of the recess 205 is exposed by way of the opening 207. These are the same if the SiO₂ layer 204 and the Si₃N₄ layer 203 are etched in the same RIE process or they are etched in different RIE processes. The state at the end of this etching process or processes is shown in FIG. 2B.

Then, the photoresist film 206 is removed, and four metal layers of Si, Ti, Pt, and Au are successively formed on the SiO₂ layer 204 by a known method, for example, a sputtering method. A patterned photoresist film (not shown) is formed on these metal layers and then, the metal layers are patterned by a known method, for example, an ion milling method. Thus, a T-shaped gate electrode 208 is formed, as shown in FIG. 2C.

As seen from FIG. 2C, the bottom of the gate electrode 208 contacts the surface of the recess 205 (i.e., the surface of the active layer 202 in the recess 205) by way of the opening 207. The overhanging parts of the electrode 208 at its top are located on the SiO₂ layer 204. At this time, as seen from FIG. 2C, undesired gaps g are formed at each side of the bottom of the electrode 208. This is because the opening 207 at the part corresponding to the Si₃N₄ layer 203 is laterally wider than that at the part corresponding to the SiO₂ layer 204.

Subsequently, only the SiO₂ layer 204 in the upper level is selectively removed by a wet etching method using buffered hydrofluoric (HF) acid (HF:NH₄F=1:6 to 1:30). In this wet etching process, the Si₃N₄ layer 203 in the lower level also is removed partially and undesirably, because obtainable etch selectivity between the Si₃N₄ layer 203 and the SiO₂ layer 204 is not sufficient. As a result, the remaining Si₃N₄ layer 203 is likely to have thickness fluctuation. (In the worst case, the Si₃N₄ layer 203 also is entirely removed by etching.) The state at this stage is shown in FIG. 2D. The remaining part of the Si₃N₄ layer 203 on the surface of the active layer 202 serves as a protection layer for the layer 202.

Thereafter, an opening for a source electrode and an opening for a drain electrode are formed at the corresponding locations of the protection layer (i.e., the remaining Si₃N₄ layer) 203 by an etching method, thereby exposing the underlying active layer 202 from the layer 203 by way of these openings. Then, a source electrode 209 and a drain electrode 210 are formed in such a way that the bottoms of the electrodes 209 and 210 contact the surface of the active layer 202 by way of their respective openings of the layer 208. The state at this stage is shown in FIG. 2E.

Finally, a necessary dielectric layer and a wiring conductive layer (both not shown) are formed on the protection layer 203 by a known method in such a way as to cover the gate electrode 208, the source electrode 209, and the drain electrode 210. Thus, the FET with the recess 205 and the T-shaped gate electrode 208 is completed.

As seen from the above-described explanation, with the prior-art method shown in FIGS. 2A to 2E, the cross-sectional shape of the opening 207 for the gate electrode 208 is not uniform or straight as desired in the state of FIG. 2B. Thus, there is a possibility that the gate electrode 208, which is formed to fill the opening 207, has a non-uniform cross-sectional shape and the undesired gaps g are formed near the bottom of the gate electrode 208. At the same time as this, the thickness of the Si₃N₄ layer 203 left as the protection layer is likely to be non-uniform. Due to these disadvantages, there is a problem that the operation characteristics of the FET tend to fluctuate and that the fabrication yield thereof tends to deteriorate.

Furthermore, unlike the prior-art method of FIGS. 1A to 1D, the surface of the recess 205 is not exposed except for the process of forming the gate electrode 208 (FIG. 2B) and thus, the possibility that the surface of the recess 205 is contaminated is low. Moreover, the thick SiO₂ layer 204 does not exist just below the overhanging parts of the gate electrode 208 and therefore, the problem of the gate parasitic capacitance increase does not occur. However, the controllability of the etching process for forming the gate electrode 208 is insufficient. As a result, there is a disadvantage that a desired uniform shape of the gate electrode 208 is difficult to be obtained.

In summary, the prior-art method of FIGS. 1A to 1D has a problem or disadvantage that the possibility that the surface of the recess 104 is contaminated is high because almost all the surface of the recess 104 is exposed during the period from the formation of the gate electrode 107 to the formation of the protection layer 108.

The prior-art method of FIGS. 2A to 2E has a problem or disadvantage that the characteristics fluctuation of the FET increases and the fabrication yield thereof degrades because obtainable controllability of the shape of the opening 207 for the gate electrode 208 is insufficient.

### SUMMARY OF THE INVENTION

Accordingly, an object of the present invention is to provide a method of fabricating a semiconductor device having a T-type gate electrode that eliminates the possibility that the surface of a recess is contaminated before and after the process of forming a gate electrode and that achieves sufficient controllability of the shape of a gate electrode, while keeping the gate parasitic capacitance due to the overhanging parts of a gate electrode low.

Another object of the present invention is to provide a method of fabricating a semiconductor device having a T-type gate electrode that suppresses the fluctuation of the operation characteristics and improves the fabrication yield, while keeping the gate parasitic capacitance due to the overhanging parts of a gate electrode low.

The above objects together with others not specifically. mentioned will become clear to those skilled in the art from the following description.

According to a first aspect of the present invention, a method of fabricating a semiconductor device is provided. This method comprises:

(a) forming a first dielectric layer on a surface of a semiconductor base material to cover a recess formed on the surface;

(b) forming a second dielectric layer on the first dielectric layer to cover the recess;

(c) selectively removing the second dielectric layer and the first dielectric layer by dry etching, thereby forming a gate opening that penetrates the second dielectric layer and the first dielectric layer to reach (or expose) the surface of the base material in the recess;

the first dielectric layer and the second dielectric layer being respectively etched at approximately equal etch rates with respect to an etchant used;

(d) forming a patterned conductive layer on the second dielectric layer to cover the gate opening, thereby forming a gate electrode with an approximately T-shaped cross section;

the gate electrode having a bottom contacted with the surface of the base material in the recess by way of the gate opening;

(e) removing the second dielectric layer left on the first dielectric layer by wet etching, thereby exposing the first dielectric layer, after the step (d);

the second dielectric layer being etched at an etch rate sufficiently greater than an etch rate of the first dielectric layer with respect to an etchant used; and

(f) forming a source electrode and a drain electrode at opposite positions with respect to the gate electrode in such a way that each of the source electrode and the drain electrode penetrates the first dielectric layer to contact the surface of the base material, after the step (e).

With the method according to the first aspect of the present invention, in the step (c), the second dielectric layer and the first dielectric layer are selectively removed by dry etching in order to form the gate opening at approximately equal etch rates with respect to an etchant used. Thus, the first and second dielectric layers are etched approximately equally in the step (c). As a result, not only the gate opening that penetrates the second and first dielectric layers is formed to reach (or expose) the surface of the base material in the recess but also the size of the gate opening is approximately uniform from its top to bottom. This solves the above-described disadvantage that the size or cross-sectional shape of the gate opening is not uniform or straight from the top to the bottom as seen in the prior-art method of FIGS. 2A to 2E.

On the other hand, in the step (e), the second dielectric layer left on the first dielectric layer is removed by wet etching in order to expose the first dielectric layer. In this step (e), the second dielectric layer is etched at an etch rate sufficiently greater than an etch rate of the first dielectric layer. Therefore, the second dielectric layer is removed while the first dielectric layer is scarcely etched.

Moreover, when the second dielectric layer is removed by wet etching in the step (e), the surface of the semiconductor base material is kept covered with the first dielectric layer. Then, in the step (f), the source electrode and the drain electrode are formed while keeping the surface of the semiconductor base material covered with the first dielectric layer. Therefore, the possibility that the surface of the recess is contaminated before and after the process of forming the gate electrode is eliminated and at the same time, sufficient controllability of the shape of the gate electrode is achieved. This leads to suppression of the fluctuation of the operation characteristics of the semiconductor device and improvement of the fabrication yield thereof.

In addition, since the second dielectric layer left below the overhanging parts of the gate electrode at the end of the step (d) is removed by wet etching in the step (e), the gate parasitic capacitance due to the overhanging parts is suppressed.

As each of the first and second dielectric layers, any dielectric layer may be used if it meets the above-identified condition for the method according to the first aspect of the invention.

In a preferred embodiment of the method according to the first aspect of the invention, the first dielectric layer is made of a dense or compact silicon-based oxide, and the second dielectric layer is made of a silicon-based oxide having a lower density than the first dielectric layer.

It is preferred that the first dielectric layer is made of a silicon-based oxide obtained by, for example, CVD (Chemical Vapor Deposition), and the second dielectric layer is made of an inorganic SOG (Spin-on Glass) material. A silicon-based oxide obtained by CVD is typically dense or compact.

An “inorganic SOG material” layer, i.e., a layer made of an inorganic SOG material, means a dielectric layer which is formed by coating an “inorganic SOG material” on a glass substrate in the form of layer by spin coating or the like, and sintering the “inorganic SOG material” thus coated under a specific condition. An “inorganic SOG material” layer typically has a lower density and a coarser structure than a silicon-based oxide layer (e.g., a SiO₂ layer) formed by CVD.

For example, a HSQ (Hydrogen Silsesquioxane) layer containing silicate as its main ingredient (i.e., a silicate-based HSQ layer) is preferably used as an “inorganic SOG material” layer. This is because a silicate-based HSQ layer has a similar property or character to a SiO₂ layer and thus, it is often used instead of a SiO₂ layer.

Many types of an “inorganic SOG material” layer have been developed and disclosed by adjusting the molecular weight, viscosity, and final property or character of the layer for specific purposes. Any one of the “inorganic SOG material” layers may be used for the invention if it meets the above-identified condition about the etch rate.

According to a second aspect of the present invention, another method of fabricating a semiconductor device is provided. This method comprises:

(a) forming a first dielectric layer on a surface of a semiconductor base material to cover a recess formed on its surface;

(b) forming a first opening that penetrates the first dielectric layer to reach the surface of the base material in the recess;

(c) forming a second dielectric layer on the first dielectric layer in such a way that part of the second dielectric layer enters the first opening to contact the surface of the base material in the recess;

(d) selectively etching back the second dielectric layer by dry etching to expose the first dielectric layer, thereby forming a pair of gate sidewalls made of the second dielectric layer in the first opening;

a second opening being formed between the pair of gate sidewalls;

the first dielectric layer and the second dielectric layer being respectively etched at approximately equal etch rates;

(e) forming a patterned conductive layer on the first dielectric layer to cover the second opening, thereby forming a gate electrode with an approximately T-shaped cross section;

the gate electrode having a bottom contacted with the surface of the base material in the recess by way of the second opening;

(f) selectively removing the first dielectric layer left on the surface of the base material by wet etching, thereby exposing the surface of the base material and the pair of gate sidewalls, after the step (e);

the first dielectric layer being etched at an etch rate sufficiently greater than an etch rate of the second dielectric layer that forms the pair of gate sidewalls; and

(g) forming a source electrode and a drain electrode at opposite positions with respect to the gate electrode in such a way that each of the source electrode and the drain electrode contacts the surface of the base material, after the step (f);

With the method according to the second aspect of the present invention, in the step (d), the second dielectric layer is selectively etched back by dry etching to expose the first dielectric layer, thereby forming the pair of gate sidewalls made of the second dielectric layer in the first opening and the second opening between the pair of gate sidewalls. In this step, the first dielectric layer and the second dielectric layer are respectively etched at approximately equal etch rates and thus, the first and second dielectric layers are etched approximately equally. As a result, the pair of gate sidewalls made of the second dielectric layer is formed in the first opening and at the same time, the second opening is formed between the pair of gate sidewalls. Since the second opening reaches the surface of the base material in the recess and at the same time, the second opening is approximately uniform except for its upper part. This solves the above-described problem that the size or cross-sectional shape of the gate opening is not uniform or straight in its lower part as seen in the prior-art method of FIGS. 2A to 2E.

On the other hand, in the step (f), the first dielectric layer left on the surface of the base material is selectively removed by wet etching, thereby exposing the surface of the base material and the pair of gate sidewalls. In this step, the first dielectric layer is etched at an etch rate sufficiently greater than an etch rate of the second dielectric layer constituting the pair of gate sidewalls and therefore, the first dielectric layer is selectively removed while the second dielectric layer (i.e., the pair of gate sidewalls) is scarcely etched.

Moreover, when the first dielectric layer left on the surface of the base material is selectively removed by wet etching in the step (f), the surface of the semiconductor base material is exposed. However, almost all the surface of the base material in the recess is covered with the gate electrode and the pair of gate sidewalls and thus, no problem will occur. Thereafter, in the step (g), the source electrode and the drain electrode are formed while keeping the state unchanged. Accordingly, the possibility that the surface of the base material in the recess is contaminated before and after the process of forming the gate electrode is eliminated and at the same time, sufficient controllability of the shape of the gate electrode is achieved. This leads to not only suppression of the fluctuation of the operation characteristics of the semiconductor device but also improvement of the fabrication yield thereof.

In addition, since the first dielectric layer left below the overhanging parts of the gate electrode at the end of the step (e) is removed by wet etching in the step (f), the gate parasitic capacitance due to the overhanging parts is suppressed.

As each of the first and second dielectric layers, any dielectric layer may be used if it meets the above-identified condition for the method according to the second aspect of the invention.

In a preferred embodiment of the method according to the second aspect of the invention, the second dielectric layer is made of a dense or compact silicon-based oxide, and the first dielectric layer is made of a silicon-based oxide having a lower density than the second dielectric layer.

It is preferred that the second dielectric layer is made of a silicon-based oxide obtained by, for example, CVD, and the first dielectric layer is made of an inorganic SOG material.

AHSQ layer containing silicate as its main ingredient (i.e., a silicate-based HSQ layer) is preferably used as an “inorganic SOG material” layer. This is due to the same reason as shown in the method of the first aspect.

According to a third aspect of the present invention, still another method of fabricating a semiconductor device is provided. This method comprises:

(a) forming a first dielectric layer on a surface of a semiconductor base material to cover a recess formed on its surface;

(b) forming a second dielectric layer on the first dielectric layer to cover the recess;

(c) forming a first opening that penetrates the second dielectric layer and the first dielectric layer to reach the surface of the base material in the recess;

(d) forming a third dielectric layer on the second dielectric layer in such a way that part of the third dielectric layer enters the first opening to contact the surface of the base material in the recess;

(e) selectively etching back the third dielectric layer by dry etching to expose the second dielectric layer, thereby forming a pair of gate sidewalls made of the third dielectric layer in the first opening;

a second opening being formed between the pair of gate sidewalls;

the second dielectric layer and the third dielectric layer being respectively etched at approximately equal etch rates;

(f) forming a patterned conductive layer on the second dielectric layer to cover the second opening, thereby forming a gate electrode with an approximately T-shaped cross section;

the gate electrode having a bottom contacted with the surface of the base material in the recess by way of the second opening;

(g) selectively removing the second dielectric layer left on the first dielectric layer by wet etching, thereby exposing the first dielectric layer and the pair of gate sidewalls, after the step (f);

the second dielectric layer being etched at an etch rate sufficiently greater than an etch rate of the third dielectric layer; and

(h) forming a source electrode and a drain electrode at opposite positions with respect to the recess in such a way each of the source electrode and the drain electrode penetrates the first dielectric layer left on the base material to contact the surface of the base material, after the step (g).

The method according to the third aspect of the present invention corresponds to one obtained by combining the above-described method of the first aspect and the above-described method of the second aspect to each other. Therefore, the method of the third aspect has the same advantages as those of the methods of the first and second aspects because of the same reasons as shown above with respect to the methods of the first and second aspects.

As each of the second and third dielectric layers, any dielectric layer may be used if it meets the above-identified condition for the method according to the first aspect of the invention.

In a preferred embodiment of the method according to the third aspect of the invention, the third dielectric layer is made of a dense or compact silicon-based oxide, and the second dielectric layer is made of a silicon-based oxide having a lower density than the third dielectric layer.

In another preferred embodiment of the method according to the third aspect of the invention, the third dielectric layer is made of a silicon-based oxide obtained by CVD, and the second dielectric layer is made of an inorganic SOG material.

In still another preferred embodiment of the method according to the third aspect of the invention, the third dielectric layer is made of SiO₂ obtained by CVD, and the second dielectric layer is made of HSQ.

In a further preferred embodiment of the method according to the third aspect of the invention, the first dielectric layer is made of a same material as the third dielectric layer.

By the way, the Japanese Non-Examined Patent Publication No. 11-214404 published in 1999 disclosed a method of fabricating a semiconductor device having a T-type gate electrode with a short gate length formed on the surface of a semiconductor base material in its recess. With this method, the pillar-like main part of the gate electrode is reinforced with a patterned dielectric layer and at the same time, the surface of the recess is protected by the same dielectric layer, thereby improving the fabrication yield of the gate electrode formation process and decreasing the characteristic or performance fluctuation through the elimination of recess surface contamination.

In the prior-art method of the Publication No. 11-214404, a Si₃N₄ layer is used as the first dielectric layer while a SiO₂ layer or an organic dielectric layer with a low dielectric constant such as a BCB layer is used as the second dielectric layer. The etch rate difference between the first and second dielectric layers is utilized to form the supporting parts (i.e., gate sidewalls) on the recess surface at each side of the gate electrode. According to the inventor's test, in this method, it was found that approximately equal etch rates were not realized in an actual dry etching process for the first and second dielectric layers as desired, and that desired etch selectivity was not achieved in an actual wet etching process for the first and second dielectric layers.

The Japanese Non-Examined Patent Publication No. 10-4102 published in 1998 disclosed a method of fabricating a semiconductor device, which achieves the formation of a T-type gate electrode with the gate length of approximately 0.05 μm uniformly with good reproducibility. In this prior-art method, a two-ingredient dielectric layer (for example, a PSG layer) formed by CVD is used as the mask layer for forming a gate opening. These two ingredients of the mask layer, for example, phosphoric acid (P₂O₅) and silicon dioxide (SiO₂), are selected in such a way as to have different etch rates in a desired wet etching process. The composition of the ingredient with a higher etch rate (e.g., P₂O₅) is set to be larger in the outer part of the mask layer and at the same time, the composition ratio of the mask layer is controlled to decrease gradually along the surface of the semiconductor base material. As a result, in the isotropic wet etching process of the mask layer, the obtainable side-etching amount is larger in the outer part of the mask layer and it decreases gradually in the inner part thereof toward the surface of the substrate. This makes it possible to form an opening with a tapered cross section in the mask layer. In this way, a T-type gate electrode with the gate length of approximately 0.05 μm (which is smaller than the opening of the mask layer in the above-identified isotropic wet etching process) is realized.

However, it is obvious that the prior-art method of the Publication No. 10-4102 is different from the methods of the invention. This is because the above-identified two-ingredient dielectric layer (e.g., a PSG layer) is used for forming a tapered opening of the mask layer.

### BRIEF DESCRIPTION OF THE DRAWINGS

In order that the present invention may be readily carried into effect, it will now be described with reference to the accompanying drawings.

FIGS. 1A to 1D are partial, schematic cross-sectional views showing the process steps of a prior-art method of fabricating a semiconductor device, respectively.

FIGS. 2A to 2E are partial, schematic cross-sectional views showing the process steps of another prior-art method of fabricating a semiconductor device, respectively.

FIGS. 3A to 3E are partial, schematic cross-sectional views showing the process steps of a method of fabricating a semiconductor device according to a first embodiment of the invention, respectively.

FIGS. 4A to 4F are partial, schematic cross-sectional views showing the process steps of a method of fabricating a semiconductor device according to a second embodiment of the invention, respectively.

FIGS. 5A to 5F are partial, schematic cross-sectional views showing the process steps of a method of fabricating a semiconductor device according to a third embodiment of the invention, respectively.

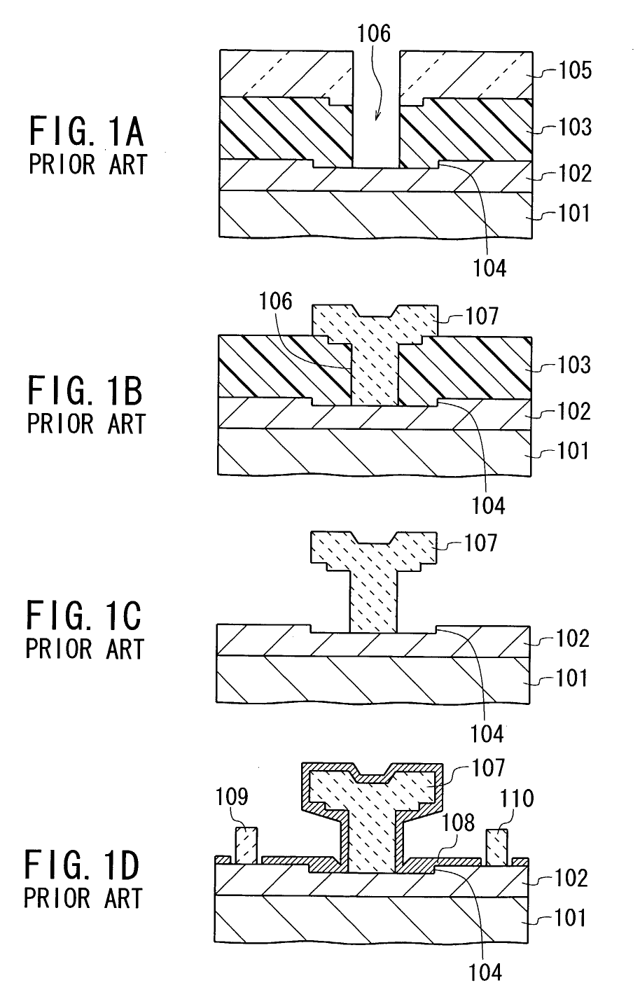

### DETAILED DESCRIPTION OF THE PREFERRED EMBODIMETNS

Preferred embodiments of the present invention will be described in detail below while referring to the drawings attached.

### First Embodiment

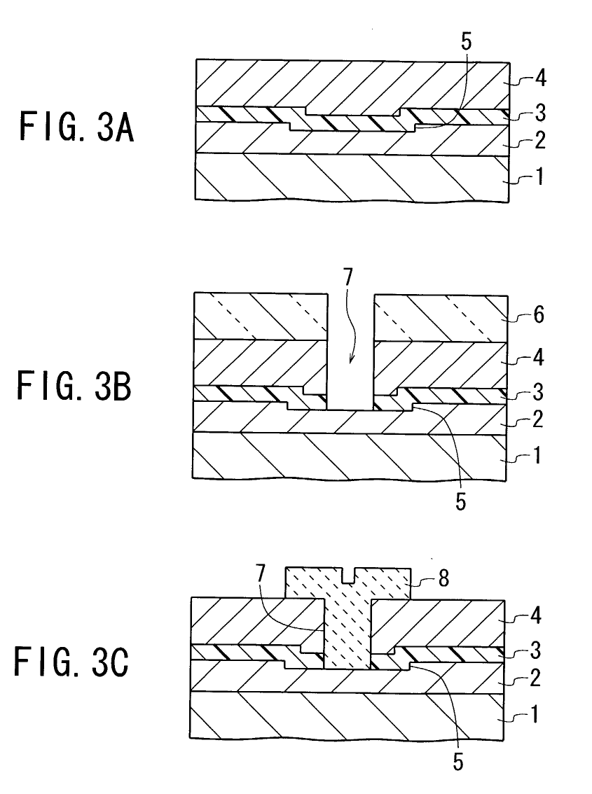

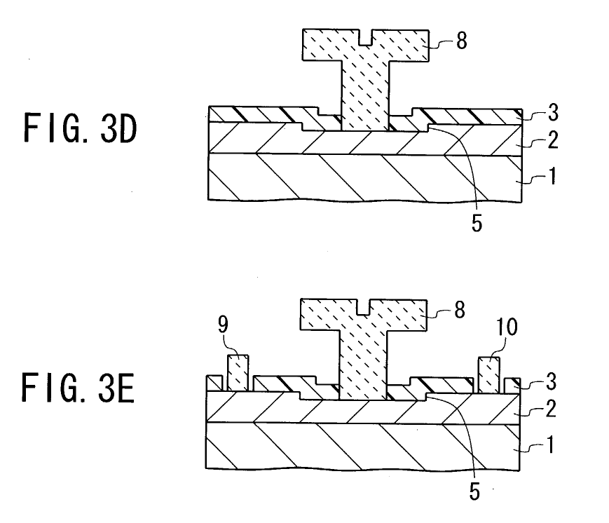

A method of fabricating a semiconductor device (i.e., a FET) according to a first embodiment of the invention is shown in FIGS. 3A to 3E.

First, as shown in FIG. 3A, an active layer 2, which is typically made of GaAs, is formed on the surface of a single-crystal semiconductor (e.g., GaAs) substrate 1 by a known epitaxial growth method. Then, the surface of the single-crystal active layer 2 thus formed is selectively etched to form a recess 5 with a specific rectangular plan shape and a specific depth. The recess 5 is located at a position in which a gate electrode will be formed later. The recess 5 is formed to cover approximately the whole width of a gate electrode. Here, the combination of the single-crystal substrate 1 and the single-crystal active layer 2 constitutes a single-crystal “semiconductor base material”.

Subsequently, a SiO₂ layer 3 with a specific thickness is formed on the active layer 2 by a plasma-enhanced CVD method in such a way as to cover the recess 5. The thickness of the SiO₂ layer 3 is set at a value of approximately 50 nm to 100 nm. This is to prevent the effect applied to the gate parasitic capacitance and to give a desired protection function to the active layer 2. Here, the thickness of the SiO₂ layer 3 is set at 100 nm.

Following this, a HSQ (Hydrogen Silsesquioxane) layer 4 with a specific thickness is formed on the SiO₂ layer 3. The thickness of the HSQ layer 4 is set at a value of approximately 300 nm to 600 nm according to the height of a gate electrode to be formed later. Here, the thickness of the HSQ layer 4 is set at 400 nm. The HSQ layer 4 is formed in the following way.

A material for the HSQ layer 4 is formed on the SiO₂ layer 3 by a spin coating method in the form of layer. Thereafter, the material thus coated is sintered under a specific condition. The structural formula of the HSQ material of the layer 4 is given as —(SiOₓH_{y})ₙ—, where x, y and n are positive constants. The state at this stage is shown in FIG. 3A.

A photoresist film 6 with a specific pattern is formed on the HSQ layer 4. Using the patterned photoresist film 6 as a mask, the HSQ layer 4 and the SiO₂ layer 3 are selectively removed by a dry etching method, forming an opening 7 for a gate electrode (i.e., a gate opening). The gate opening 7 penetrates vertically the layers 4 and 3 and reaches the surface of the active layer 2 in the recess 5 (i.e., reaches the surface of the recess 5). This dry etching process, which is an anisotropic etching process, is carried out by a RIE (Reactive Ion Etching) method using the combination of CF₄ and H₂ as an etching gas. The etch rates for the layers 4 and 3 are approximately the same, in other words, the layers 4 and 3 are removed approximately equal etch rates. This was actually confirmed by the inventor's test.

Thus, as shown in FIG. 3B, the gate opening 7 that penetrates the HSQ layer 4 and the SiO₂ layer 3 has a uniform or straight cross section without no steps. In the state of FIG. 3B, the surface of the active layer 2 in the recess 5 is partially exposed through the opening 7.

After the photoresist film 6 is removed, four metal layers of WSi, Ti, Pt, and Au are successively formed on the HSQ layer 4 by a known method (e.g., a sputtering method). Thereafter, a patterned photoresist film (not shown) is formed on these metal layers thus formed. Using the photoresist film as a mask, the four metal layers are patterned by a known method (e.g., an ion milling method). Thus, a T-type gate electrode 8 having an approximately T-shaped cross section is formed, as shown in FIG. 3C.

As clearly seen from FIG. 3C, the bottom of the gate electrode 8 contacts the surface of the recess 5 by way of the opening 7. The overhanging parts of the T-shaped electrode 8, which are formed at its top to protrude laterally at each side of the pillar-shaped main part, are located on the surface of the HSQ layer 4. The main part of the electrode 8 is entirely located in the opening 7.

The whole width of the gate electrode 8, which is measured perpendicular to the straight line connecting a source electrode and a drain electrode to each other, is set in such a way as to approximately in accordance with the whole width of the recess 5. As seen from FIG. 3C, the whole length of the gate electrode 8, which is measured along the straight line connecting the source and drain electrodes to each other, is shorter than the length of the recess 5.

Subsequently, the HSQ layer 4 is entirely removed by a wet etching method using buffered hydrofluoric (HF) acid (HF:NH₄F=1:6 to 1:30). This is to remove the HSQ layer 4 located below the overhanging parts of the gate electrode 8 to suppress the gate parasitic capacitance, thereby preventing the characteristic or performance of the semiconductor device (i.e., FET) from deteriorating.

According to the inventor's test, it was confirmed that a desired etch selectivity was obtainable in this wet etching process. Specifically, the etch rate of the HSQ layer 4 was 800 angstrom/sec while the etch rate of the SiO₂ layer 3 was 10 angstrom/sec, which provided a desired high etch selectivity between the layers 4 and 3.

As a result, the HSQ layer 4 is selectively and isotropically etched while the SiO₂ layer 3 is scarcely etched in the said wet etching process. This means that the thickness of the SiO₂ layer 3 scarcely decreases in this process and the initial thickness of the SiO₂ layer 3 is kept approximately unchanged at the end of this wet etching process. The state at this stage is shown in FIG. 3D.

The SiO₂ layer 3 left on the active layer 2 serves as a protection layer for protecting the surface of the layer 2 including the recess 5.

Following this, by any etching method, an opening for a source electrode 9 and an opening for a drain electrode 10 are formed in the remaining SiO₂ layer 3, thereby partially exposing the active layer 3 through these openings. Then, a source electrode 9 and a drain electrode 10 are formed by a known method in such a way as to contact the surface of the layer 3 by way of the respective openings. The state at this stage is shown in FIG. 3E.

For example, the source and drain electrodes 9 and 10 are formed by a known lift-off method in the following way. Specifically, first, an appropriate mask layer (not shown) is formed on the SiO₂ layer 3. The mask layer has a window corresponding to the opening for the source electrode 9 and a window corresponding to the opening for the drain electrode 10. Needless to say, the mask layer is formed to cover the gate electrode 8. Next, an AuGeNi alloy layer (not shown) with a specific thickness is formed on the mask layer by an evaporation method. Thereafter, the mask layer is removed. Thus, the AuGeNi alloy layer is removed along with the mask layer, resulting in the source and drain electrodes 9 and 10, as shown in FIG. 3E.

As seen from FIG. 3E, the bottoms of the source and drain electrodes 9 and 10 contact the surface of the active layer 2 by way of their respective openings of the SiO₂ layer 3. The tops of the electrodes 9 and 10 protrude upwardly from the layer 3. The electrodes 9 and 10 are located at opposite sides of the recess 5 (i.e., the gate electrode 8).

Finally, a necessary dielectric layer or layers and a wiring conductive layer or layers (both not shown) are successively formed on the SiO₂ protection layer 3 by a known method or methods in such a way as to cover the gate electrode 8, the source electrode 9, and the drain electrode 10. Thus, the semiconductor device or FET with the recess 5 and the T-shaped gate electrode 8 is completed.

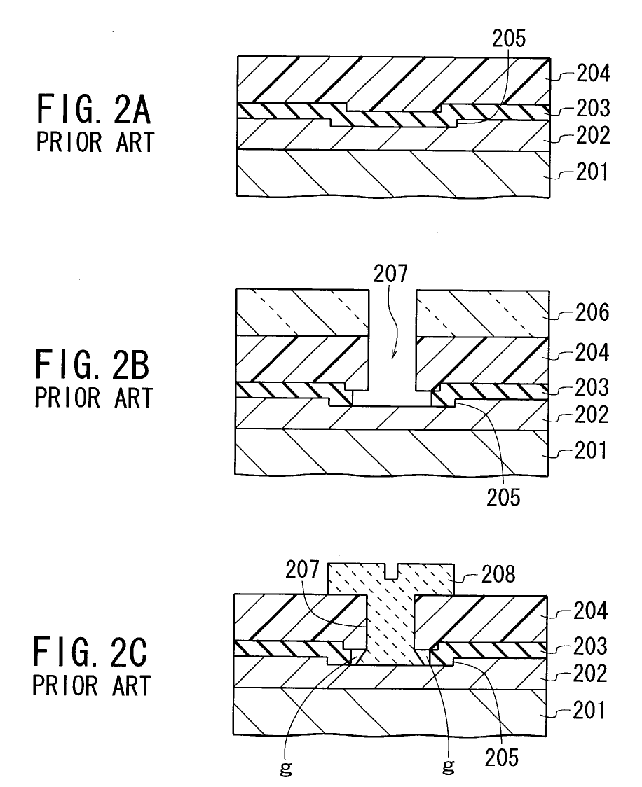

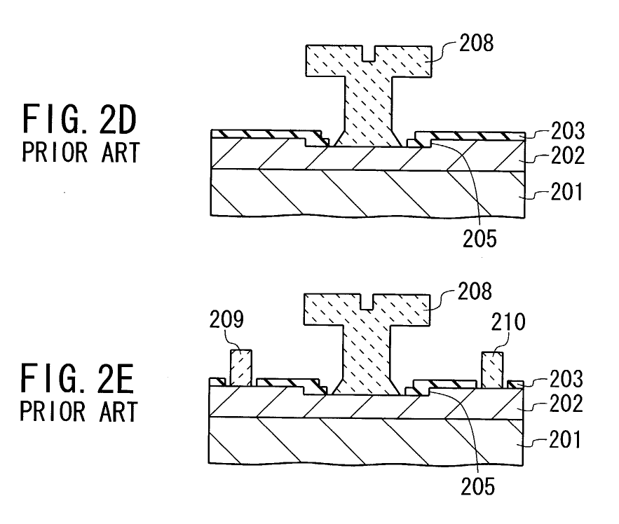

With the method of a semiconductor device according to the first embodiment of the invention, as explained above in detail, the SiO₂ layer 3 and the HSQ layer 4 are successively formed on the surface of the active layer 2 (i.e., on the surface of the semiconductor base material) in such a way as to cover the recess 5 and then, these layers 3 and 4 are selectively removed in the same dry etching process. In this dry etching process, the etching condition is controlled in such a way that the layers 3 and 4 have approximately equal etch rates and therefore, they are anisotropically etched approximately equally. As a result, as shown in FIG. 3B, the gate opening 7 is formed to penetrate the layers 3 and 4 and to reach the surface of the recess 5 and at the same time, the size of the gate opening 7 is formed approximately uniform (in other words, the vertical cross section of the opening 7 is approximately straight) from the top to the bottom. This solves the above-described problem or disadvantage that the size or cross-sectional shape of the gate opening 7 is not uniform or straight from the top to the bottom as seen in the prior-art method of FIGS. 2A to 2E.

On the other hand, in the wet etching process for removing the HSQ layer 4, the HSQ layer 4 is etched at an etch rate sufficiently greater than an etch rate of the SiO₂ layer 3. Therefore, only the HSQ layer 4 is removed selectively and isotropically to expose the underlying SiO₂ layer 3. Since the SiO₂ layer 3 is scarcely etched in this process, the thickness of the layer 3 is scarcely reduced. Thus, the initial thickness of the layer 3 is kept almost unchanged at the end of this wet etching process.

Moreover, when the HSQ layer 4 is removed in the wet etching process after forming the gate electrode 8, the surface of the active layer 2 including the recess 5 is kept covered with the remaining SiO₂ layer 3. Thereafter, the source electrode 9 and the drain electrode 10 are formed while keeping the surface of the active layer 2 covered with the layer 3. Therefore, the possibility that the surface of the recess 5 is contaminated before and after the process of forming the gate electrode 8 is eliminated and at the same time, sufficient controllability of the shape of the gate electrode 8 is achieved. This leads to suppression of the fluctuation of the operation characteristics of the semiconductor device (i.e., the FET) and improvement of the fabrication yield thereof.

In addition, since the HSQ layer 4 left below the overhanging parts of the gate electrode 8 at the end of the wet etching process is removed by the subsequent wet etching process, the gate parasitic capacitance due to the overhanging parts is suppressed as desired.

### Second Embodiment

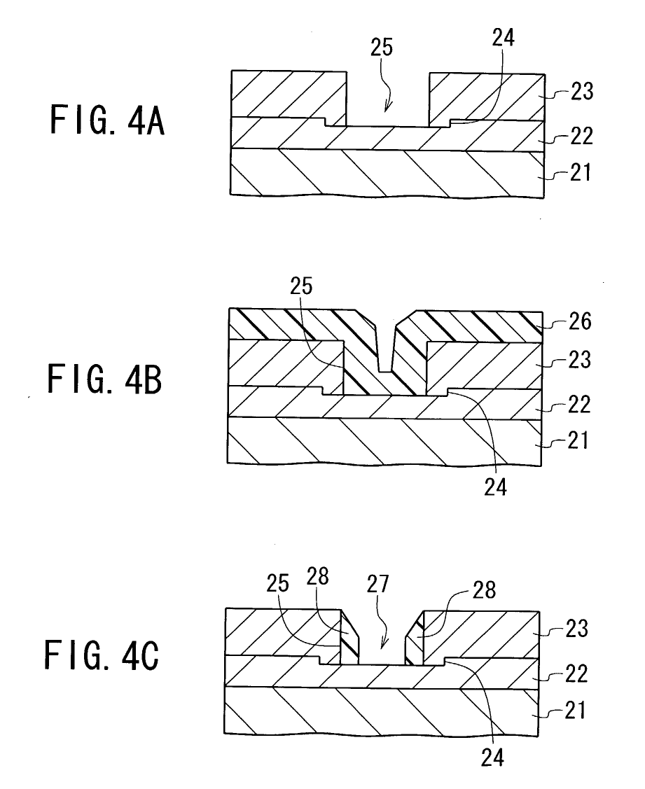

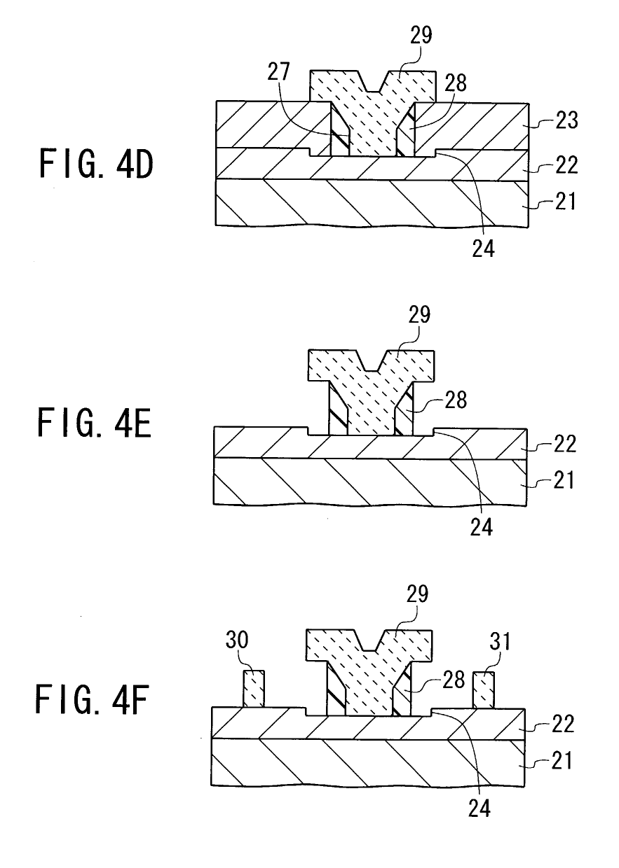

FIGS. 4A to 4F show a method of fabricating a semiconductor device (i.e., a FET) according to a second embodiment of the invention.

First, as shown in FIG. 4A, an active layer 22, which is typically made of GaAs, is formed on the surface of a single-crystal semiconductor (e.g., GaAs) substrate 21 by a known epitaxial growth method. Then, the surface of the single-crystal active layer 22 thus formed is selectively etched to form a recess 24 with a specific rectangular plan shape and a specific depth. The recess 24 is located at a position in which a gate electrode will be formed later. The recess 24 is formed to cover approximately the whole width of a gate electrode. Here, the combination of the single-crystal substrate 21 and the single-crystal active layer 22 constitutes a single-crystal “semiconductor base material”.

Next, a HSQ layer 23, which is the same as the HSQ layer 4 used in the method of the first embodiment, is formed on the active layer 22 by the same method as used in the first embodiment. The thickness of the layer 23 is set at 500 nm.

Thereafter, the HSQ layer 23 is selectively removed by a known dry etching method, thereby forming a first opening 25. The first opening 25 penetrates the layer 23 vertically to reach the surface of the active layer 22 in the recess 24. The surface of the recess 24 is partially exposed through the first opening 25. The size of the opening 25 is determined taking the sizes of a gate electrode and a pair of gate sidewalls to be formed later into consideration. The opening 25 is longer than the opening 7 in the first embodiment, because a pair of gate sidewalls is formed in the opening 25 along with the gate electrode. The state at this stage is shown in FIG. 4A.

A SiO₂ layer 26 with a thickness of 400 nm is formed on the HSQ layer 23 by a plasma-enhanced CVD method. The layer 26 thus formed has a part that exists in the first opening 25 to fill the same, as shown in FIG. 4B. The part of the layer 26 existing in the opening 25 contacts the exposed surface of the recess 24.

Then, the SiO₂ layer 26 is etched back by the same anisotropic dry etching method as used in the first embodiment. Thus, the part of the SiO₂ layer 26 located on the HSQ layer 23 and the part of the SiO₂ layer 26 located in the middle of the first opening 25 are selectively removed, thereby exposing the HSQ layer 23. As a result, as shown in FIG. 4C, part of the SiO₂ layer 26 is selectively left along the opposing inner side faces of the first opening 25. The part of the layer 26 thus left constitutes a pair of dielectric gate sidewalls 28. The hollow space between the pair of gate sidewalls 28 in the first opening 25 serves as a second opening 27.

In the state of FIG. 4C, the surface of the recess 24 is exposed by way of the second opening 27. In the dry etching method for etching back the SiO₂ layer 26, the HSQ layer 23 and the SiO₂ layer 26 have approximately equal etch rates, in other words, these layers 23 and 26 are etched at approximately equally. Therefore, the etching process of the SiO₂ layer 26 in the upper level is stopped when the etching action of the HSQ layer 23 in the lower level begins. Thus, the pair of gate sidewalls 28 and the second opening 27 for a gate electrode are obtained as desired, as shown in FIG. 4C.

Subsequently, in the same way as that of the first embodiment, four metal layers of WSi, Ti, Pt, and Au are successively formed on the HSQ layer 23 and patterned, thereby forming a T-type gate electrode 29 with an approximately T-shaped cross section, as shown in FIG. 4D. The bottom of the gate electrode 29 contacts the surface of the recess 24 by way of the second opening 27. The overhanging parts of the gate electrode 29, which are formed at its top to protrude laterally at each side of the pillar-shaped main part, are located on the surface of the HSQ layer 23. The main part of the electrode 29 is entirely located in the opening 27. The pair of gate sidewalls 28, which is made of the remaining SiO₂ layer 26, is located at each side of the main part of the electrode 29 in the opening 25. The pair of gate sidewalls 28 serves as a pair of supporting or reinforcing portions or members for the gate electrode 29.

Following this, to suppress the gate parasitic capacitance, the HSQ layer 23 is entirely removed by the same wet etching method using buffered hydrofluoric (HF) acid as used in the first embodiment. In this etching process, a desired high etch selectivity is obtainable between the HSQ layer 23 and the gate sidewalls 28 made of SiO₂ and therefore, the HSQ layer 23 is etched selectively and isotropically while the gate sidewalls 28 are scarcely etched. This means that the thickness of the sidewalls 28 scarcely decreases through the etching process, and the initial thickness thereof is kept approximately unchanged. The state at this stage is shown in FIG. 4E, in which the surface of the active layer 22 is exposed except for the areas covered with the gate electrode 29 and the pair of sidewalls 28.

In the same way as used in the first embodiment, a source electrode 30 and a drain electrode 31 are formed on the exposed surface of the active layer 22. The bottoms of the source and drain electrodes 30 and 31 contact the surface of the layer 22. The electrodes 30 and 31 are located at opposite sides to each other with respect to the recess 24.

Finally, a necessary dielectric layer and a wiring conductive layer (both not shown) are successively formed on the active layer 22 by a known method or methods in such a way as to cover the gate electrode 29, the source electrode 30, and the drain electrode 31. Thus, the semiconductor device or FET with the recess 24, the T-shaped gate electrode 29, and the pair of gate sidewalls 28 is completed.

With the method of a semiconductor device according to the second embodiment of the invention, as shown in FIGS. 4A to 4F, the HSQ layer 23 is formed on the active layer 22 in such a way as to cover the recess 24, and the first opening 25 is formed to penetrate the HSQ layer 23, and then, the SiO₂ layer 26 for forming the pair of gate sidewalls 28 is formed on the HSQ layer 23. Thereafter, the SiO₂ layer 26 is etched back in the dry etching process. In this dry etching process, the etching condition is controlled in such a way that the SiO₂ layer 26 and the HSQ layer 23 have approximately equal etch rates and therefore, they are anisotropically etched approximately equally. As a result, as shown in FIG. 4C, the SiO₂ layer 26 is partially left in the first opening 25 to thereby form the pair of gate sidewalls 28 and at the same time, the second opening 27 is formed to expose the surface of the recess 24 between the pair of sidewalls 28. Moreover, there is no possibility that the SiO₂ layer 26 is undesirably left on the remaining HSQ layer 23.

On the other hand, in the wet etching step for removing the HSQ layer 23, the HSQ layer 23 is etched at an etch rate sufficiently greater than an etch rate of the gate sidewalls 28 made of SiO₂. Therefore, only the HSQ layer 23 is removed selectively and isotropically while the sidewalls 28 are scarcely etched. Since the gate sidewalls 28 are scarcely etched in this process, substantially no reduction occurs in the thickness of the sidewalls 28. Thus, the initial thickness of the gate sidewalls 28 is kept almost unchanged at the end of this process.

Moreover, when the HSQ layer 23 is removed by wet etching after forming the gate electrode 29, the surface of the active layer 22 including the recess 24 is exposed, as shown in FIG. 4E. However, in this state, almost all the surface of the recess 24 is covered with the gate electrode 29 and the pair of gate sidewalls 28. Thereafter, the source and drain electrodes 30 and 31 are formed on the active layer 22 immediately after the removal of the HSQ layer 23. As a result, the possibility that the exposed surface of the recess 24 is contaminated before and after the process of forming the gate electrode 29 is extremely low and at the same time, sufficient controllability of the shape of the gate electrode 29 is achieved. This leads to suppression of the fluctuation of the operation characteristics of the semiconductor device (i.e., the FET) and improvement of the fabrication yield thereof.

In addition, since the HSQ layer 23 left below the overhanging parts of the gate electrode 29 at the end of the wet etching process is removed entirely by the subsequent wet etching process, the gate parasitic capacitance due to the overhanging parts is suppressed as desired.

The method of the second embodiment has an additional advantage that the mechanical strength of the gate electrode 29 is higher than that of the first embodiment, because the pair of sidewalls 28 are provided.

### Third Embodiment

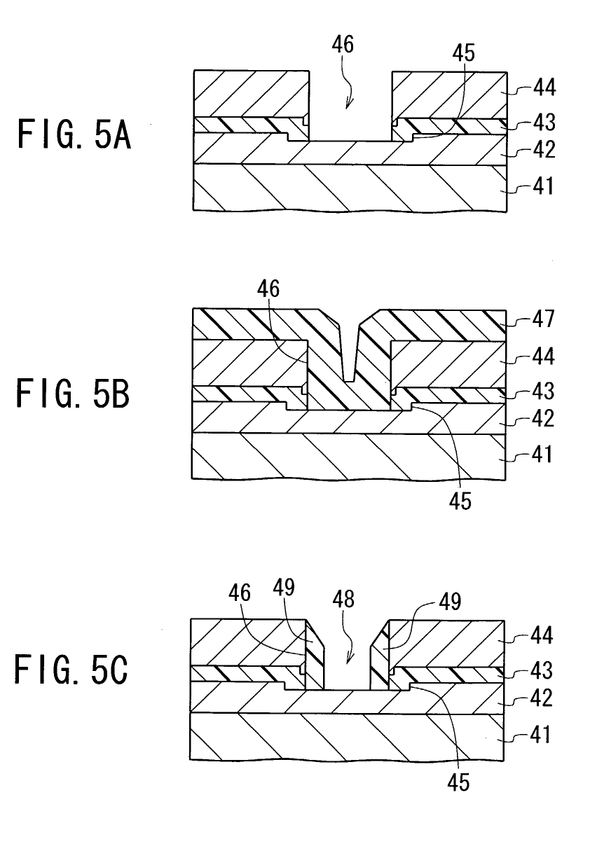

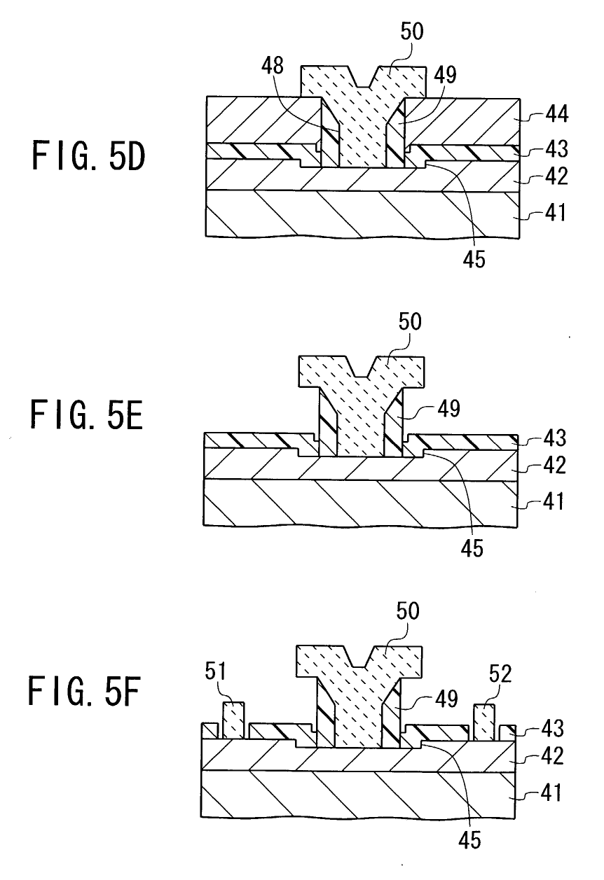

FIGS. 5A to 5F show a method of fabricating a semiconductor device (i.e., a FET) according to a third embodiment of the invention. This method corresponds to the combination of the methods of the above-described first and second embodiments.

First, as shown in FIG. 5A, an active layer 42, which is typically made of GaAs, is formed on the surface of a single-crystal semiconductor (e.g., GaAs) substrate 41 by a known epitaxial growth method. Then, the surface of the single-crystal active layer 42 thus formed is selectively etched to form a recess 45 with a specific rectangular plan shape and a specific depth. The recess 45 is located at a position in which a gate electrode will be formed later. The recess 45 is formed to cover approximately the whole width of a gate electrode. Here, the combination of the single-crystal substrate 41 and the single-crystal active layer 42 constitutes a single-crystal “semiconductor base material”.

Next, a SiO₂ layer 43 with a thickness of 100 nm is formed on the active layer 42 by the same plasma-enhanced CVD method as used in the first embodiment. Then, a HSQ layer 44 with a thickness of 400 nm is formed on the SiO₂ layer 43 thus formed by the same method (i.e., the combination of spin coating and sintering) as used in the first embodiment.

Thereafter, a photoresist film (not shown) with a specific pattern is formed on the HSQ layer 44. Using the patterned photoresist film as a mask, the HSQ layer 44 and the SiO₂ layer 43. are selectively removed by a dry etching method, forming a first opening 46. The first opening 46 penetrates vertically the layers 44 and 43 and reaches the surface of the active layer 42 in the recess 45 (i.e., reaches the surface of the recess 45). The size of the first opening 46 is determined taking the sizes of a gate electrode and a pair of gate sidewalls to be formed later into consideration. The state at this stage is shown in FIG. 5A.

In this dry etching process, the etch rates for the HSQ layer 44 and the SiO₂ layer 43 are controlled to be approximately equal and therefore, the first opening 46 that penetrates the layers 44 and 43 has a uniform or straight cross section without no steps, as shown in FIG. 5A. In the state of FIG. 5A, almost all the surface of the active layer 42 in the recess 45 is exposed through the first opening 46.

Following this process, a SiO₂ layer 47 with a thickness of 400 nm is formed on the HSQ layer 44 by a plasma-enhanced CVD method. The SiO₂ layer 47 thus formed has a part that exists in the first opening 46 to fill the same, as shown in FIG. 5B. The part existing in the opening 46 is contacted with the exposed surface of the recess 45.

The SiO₂ layer 47 is then etched back by the same anisotropic dry etching method as used in the first embodiment. Thus, the part of the SiO₂ layer 47 located on the HSQ layer 44 and the part of the layer 47 located in the middle of the opening 46 are selectively removed, thereby exposing the underlying HSQ layer 44. As a result, as shown in FIG. 5C, part of the SiO₂ layer 47 is selectively left in the first opening 46 along its opposing inner side faces. The part of the SiO₂ layer 47 thus left in the opening 46 constitutes a pair of dielectric gate sidewalls 49. The hollow space between the pair of gate sidewalls 49 in the first opening 46 forms a second opening 48 for a gate electrode.

In the state of FIG. 5C, the surface of the recess 45 is exposed by way of the second opening 48. In the above-described dry etching method for etching back the SiO₂ layer 47, the HSQ layer 44 and the SiO₂ layer 47 have approximately equal etch rates, in other words, these layers 44 and 47 are etched at approximately equally. Therefore, the etching process of the SiO₂ layer 47 in the upper level is stopped when the etching action of the HSQ layer 44 in the lower level begins. Thus, the pair of gate sidewalls 49 and the gate opening 48 are obtained as desired, as shown in FIG. 5C.

Subsequently, in the same way as the first embodiment, four metal layers of WSi, Ti, Pt, and Au are successively formed on the HSQ layer 44 to be patterned, thereby forming a T-type gate electrode 50 with an approximately T-shaped cross section, as shown in FIG. 5D. The bottom of the gate electrode 50 contacts the surface of the recess 45 by way of the second opening 48. The overhanging parts of the electrode 50, which are formed at its top to protrude laterally at each side of the pillar-shaped main part, is located on the HSQ layer 44. The main part of the electrode 50 is entirely located in the second opening 48. The pair of gate sidewalls 49, which is made of the remaining SiO₂ layer 47, is located at each side of the main part of the electrode 50 in the first opening 46. The pair of gate sidewalls 49 serves as a pair of supporting or reinforcing portions or members for the gate electrode 50.

Thereafter, to suppress the gate parasitic capacitance, the HSQ layer 44 is entirely removed by the same wet etching method using buffered hydrofluoric (HF) acid as used in the first embodiment. In this wet etching process, a desired high etch selectivity is obtainable between the HSQ layer 44 and the gate sidewalls 49 made of SiO₂. Therefore, the HSQ layer 44 is etched selectively and isotropically while the gate sidewalls 49 are scarcely etched. This means that the thickness of the sidewalls 49 scarcely decreases through this wet etching process and the initial thickness thereof is kept approximately unchanged. The state at this stage is shown in FIG. 5E, in which all the surface of the active layer 42 is covered with the gate electrode 50, the gate sidewalls 49, and the remaining SiO₂ layer 43.

In the same way as used in the first embodiment, a source electrode 51 and a drain electrode 52 are formed on the surface of the active layer 42. The bottoms of the source and drain electrodes 51 and 52 contact the surface of the layer 42. The tops of the electrodes 51 and 52 protrude upwardly from the layer 42. The electrodes 51 and 52 are located at opposite sides with respect to the recess 45.

Finally, a necessary dielectric layer and a wiring conductive layer (both not shown) are successively formed on the SiO₂ layer 43 by a known method or methods in such a way as to cover the gate electrode 50, the source electrode 51, and the drain electrode 52. Thus, the semiconductor device or FET with the recess 45, the T-shaped gate electrode 50, and the pair of gate sidewalls 49 is completed.

As explained above, the method of a semiconductor device according to the third embodiment of the invention corresponds to the combination of the methods of the above-described first and second embodiments. Specifically, the method of the third embodiment corresponds to one obtained by adding the process of the pair of gate sidewalls 49 to the method of the first embodiment, in other words, to one obtained by adding the process of forming the protecting SiO₂ layer 43 to the method of the second embodiment. Therefore, the method of the third embodiment has both of the advantages of the first embodiment and those of the second embodiment.

### Variations

Needless to say, the present invention is not limited to the above-described first to third embodiments, because they are preferred examples of the invention. Any change or modification may be added to them within the spirit of the invention.

For example, the combination of a single-crystal semiconductor substrate and a single-crystal active layer formed thereon is used as a single-crystal “semiconductor base material” in the above-described embodiments. However, the configuration of the “semiconductor base material” is not limited to this. For example, the active layer can be cancelled, in which the “semiconductor base material” is formed by the semiconductor substrate alone. It is needless to say that the “semiconductor base material” may have any other configuration if it has a crystalline region in the surface area and a recess is formed in the crystalline region.

While the preferred forms of the present invention have been described, it is to be understood that modifications will be apparent to those skilled in the art without departing from the spirit of the invention. The scope of the present invention, therefore, is to be determined solely by the following claims.

What is claimed is:

1. A method of fabricating a semiconductor device, comprising the steps of:
(a) forming a first dielectric layer on a surface of a semiconductor base material to cover a recess formed on the surface;
(b) forming a second dielectric layer on the first dielectric layer to cover the recess;
(c) selectively removing the second dielectric layer and the first dielectric layer by dry etching, thereby forming a gate opening that penetrates the second dielectric layer and the first dielectric layer to reach the surface of the base material in the recess;
the first dielectric layer and the second dielectric layer being respectively etched at approximately equal etch rates with respect to an etchant used;
(d) forming a patterned conductive layer on the second dielectric layer to cover the gate opening, thereby forming a gate electrode with an approximately T-shaped cross section the gate electrode having a bottom contacted with the surface of the base material in the recess by way of the gate opening;
(e) removing the second dielectric layer left on the first dielectric layer by wet etching, thereby exposing the first dielectric layer, after the step (d);
the second dielectric layer being etched at an etch rate sufficiently greater than an etch rate of the first dielectric layer with respect to an etchant used; and
(f) forming a source electrode and a drain electrode at opposite positions with respect to the gate electrode in such a way each of the source electrode and the drain electrode penetrates the first dielectric layer to contact the surface of the base material, after the step (e).

2. The method according to claim 1, wherein the first dielectric layer is made of a dense or compact silicon-based oxide, and the second dielectric layer is made of a silicon-based oxide having a lower density than the first dielectric layer.

3. The method according to claim 1, wherein the first dielectric layer is made of a silicon-based oxide obtained by CVD (Chemical Vapor Deposition), and the second dielectric layer is made of an inorganic SOG (Spin-on Glass) material.

4. The method according to claim 1, wherein the first dielectric layer is made of SiO₂ obtained by CVD (Chemical Vapor Deposition), and the second dielectric layer is made of HSQ (Hydrogen Silsesquioxane).

5. A method of fabricating a semiconductor device, comprising the steps of:
(a) forming a first dielectric layer on a surface of a semiconductor base material to cover a recess formed on its surface;
(b) forming a first opening that penetrates the first dielectric layer to reach the surface of the base material in the recess;
(c) forming a second dielectric layer on the first dielectric layer in such a way that part of the second dielectric layer enters the first opening to contact the surface of the base material in the recess;
(d) selectively etching back the second dielectric layer by dry etching to expose the first dielectric layer, thereby forming a pair of gate sidewalls made of the second dielectric layer in the first opening;
a second opening being formed between the pair of gate sidewalls;
the first dielectric layer and the second dielectric layer being respectively etched at approximately equal etch rates;
(e) forming a patterned conductive layer on the first dielectric layer to cover the second opening, thereby forming a gate electrode with an approximately T-shaped cross section;
the gate electrode having a bottom contacted with the surface of the base material in the recess by way of the second opening;
(f) selectively removing the first dielectric layer left on the base material by wet etching, thereby exposing the surface of the base material and the pair of gate sidewalls, after the step (e);
the first dielectric layer being etched at an etch rate sufficiently greater than an etch rate of the second dielectric layer that forms the pair of gate sidewalls; and
(g) forming a source electrode and a drain electrode at opposite positions with respect to the recess in such a way that each of the source electrode and the drain electrode contacts the surface of the base material, after the step (f).

6. The method according to claim 5, wherein the first dielectric layer is made of a dense or compact silicon-based oxide, and the second dielectric layer is made of a silicon-based oxide having a lower density than the first dielectric layer.

7. The method according to claim 5, wherein the first dielectric layer is made of a silicon-based oxide obtained by CVD, and the second dielectric layer is made of an inorganic SOG material.

8. The method according to claim 5, wherein the first dielectric layer is made of SiO₂ obtained by CVD, and the second dielectric layer is made of HSQ.

9. A method of fabricating a semiconductor device, comprising the steps of:
(a) forming a first dielectric layer on a surface of a semiconductor base material to cover a recess formed on its surface;
(b) forming a second dielectric layer on the first dielectric layer to cover the recess;
(c) forming a first opening that penetrates the second dielectric layer and the first dielectric layer to reach the surface of the base material in the recess;
(d) forming a third dielectric layer on the second dielectric layer in such a way that part of the third dielectric layer enters the first opening to contact the surface of the base material in the recess;
(e) selectively etching back the third dielectric layer by dry etching to expose the second dielectric layer, thereby forming a pair of gate sidewalls made of the third dielectric layer in the first opening;
a second opening being formed between the pair of gate sidewalls;
the second dielectric layer and the third dielectric layer being respectively etched at approximately equal etch rates;
(f) forming a patterned conductive layer on the second dielectric layer to cover the second opening, thereby forming a gate electrode with an approximately T-shaped cross section;
the gate electrode having a bottom contacted with the surface of the base material in the recess by way of the second opening;
(g) selectively removing the second dielectric layer left on the first dielectric layer by wet etching, thereby exposing the first dielectric layer and the pair of gate sidewalls, after the step (f);
the second dielectric layer being etched at an etch rate sufficiently greater than an etch rate of the third dielectric layer; and
(h) forming a source electrode and a drain electrode at opposite positions with respect to the recess in such a way each of the source electrode and the drain electrode penetrates the first dielectric layer left on the base material to contact the surface of the base material, after the step (g).

10. The method according to claim 9, wherein the third dielectric layer is made of a dense or compact silicon-based oxide, and the second dielectric layer is made of a silicon-based oxide having a lower density than the third dielectric layer.

11. The method according to claim 9, wherein the third dielectric layer is made of a silicon-based oxide obtained by CVD, and the second dielectric layer is made of an inorganic SOG material.

12. The method according to claim 9, wherein the third dielectric layer is made of SiO₂ obtained by CVD, and the second dielectric layer is made of HSQ.

13. The method according to claim 9, wherein the first dielectric layer is made of a same material as the third dielectric layer.
